(19) United States
(12) Patent Application Publication
(10) Pub. No.: US 2021/0286170 A1
(43) Pub. Date: Sep. 16, 2021

(54) SEMICONDUCTOR DEVICE, DISPLAY UNIT, AND ELECTRONIC APPARATUS

(71) Applicant: SONY SEMICONDUCTOR SOLUTIONS CORPORATION, Kanagawa (JP)

(72) Inventors: KUNIHIKO MORI, TOKYO (JP); KATSUYUKI KATO, KANAGAWA (JP); KOICHI IKEDA, KANAGAWA (JP); SHUSAKU YANAGAWA, KANAGAWA (JP)

(21) Appl. No.: 16/334,502

(22) PCT Filed: Sep. 5, 2017
(86) PCT No.: PCT/JP2017/031931

§ 371 Date: Mar. 19, 2019

(30) Foreign Application Priority Data
Oct. 19, 2016 (JP) 2016-205224

(51) Int. Cl. G02B 26/08; B81B 3/00; G02B 27/01; H04N 13/344

(52) U.S. Cl. CPC G02B 26/0858; B81B 3/0021; G02B 27/0172; H04N 13/344; G02B 2027/0134; B81B 2203/053; B81B 2201/047; B81B 2201/032; B81B 2207/053

(57) ABSTRACT

A semiconductor device according to one embodiment of the present disclosure includes a substrate, a plurality of structures arranged in a matrix and each having a planar part, and a plurality of piezoelectric actuators disposed on the substrate and configured to move each of the plurality of structures along a direction perpendicular to one surface of the substrate.

### TECHNICAL FIELD

The present disclosure relates to a semiconductor device used in, for example, a stereoscopic image display unit, and to a display unit and an electronic apparatus each including the semiconductor device.

### BACKGROUND ART

In a general 3D display, a screen is placed at a position of a real image, and the screen is displaced in a depth direction on a pixel unit basis to thereby change a depth position of a virtual image. With the 3D display, even when the displacement from the position of the real image in the depth direction is on the order of several tens of μm, the depth position of the virtual image is allowed to be displaced in a range of several tens of cm to near infinity, depending on an optical system. The displacement of the screen for each pixel in the depth direction is mainly achieved by micro electro mechanical systems (MEMS) (see, for example, PTL 1).

### CITATION LIST

### Patent Literature

PTL 1: Japanese Unexamined Patent Application Publication No. 2015-161765

### SUMMARY OF THE INVENTION

Meanwhile, development of a head-mounted 3D display has been in progress in recent years. In order to achieve the above-described extensive depth information in a small display such as the head-mounted display, the above-described displacement on the order of several tens of μm in the depth direction should be performed at as small a pitch as several tens of μm, for example. For this purpose, it is desired to achieve a piston-type array device allowed to largely shift on the order of 10 μm, for example, at a small pitch on the order of several tens of μm and along a direction perpendicular to an in-plane direction.

It is desirable to provide a semiconductor device, a display unit, and an electronic apparatus allowed to largely shift along the direction perpendicular to the in-plane direction at the small pitch.

A semiconductor device according to one embodiment of the present disclosure includes a substrate, a plurality of structures arranged in a matrix and each having a planar part, and a plurality of piezoelectric actuators disposed on the substrate and configured to move each of the plurality of structures along the direction perpendicular to one surface of the substrate.

A display unit according to one embodiment of the present disclosure includes an optical system including a lens and a display device, and includes the semiconductor device according to the above-described one embodiment as the display device.

An electronic apparatus according to one embodiment of the present disclosure includes the display unit according to the above-described one embodiment.

In the semiconductor device according to one embodiment of the present disclosure, the display unit according to one embodiment of the present disclosure, and the electronic apparatus according to one embodiment of the present disclosure, a plurality of structures each having a planar part is respectively disposed on the substrate via a plurality of piezoelectric actuators that allows the structures to move in the direction perpendicular to the one surface of the substrate. This makes it possible to independently shift the plurality of structures each having the planar part in the direction perpendicular to the one surface of the substrate.

In accordance with the semiconductor device according to one embodiment of the present disclosure, the display unit according to one embodiment of the present disclosure, and the electronic apparatus according to one embodiment of the present disclosure, the plurality of piezoelectric actuators that allows the plurality of structures to move along the direction perpendicular to one surface of the substrate is disposed between the plurality of structures each having a planar part and the substrate. Accordingly, it is possible to largely change the distance of the plurality of structures each having the planar part with respect to the one surface of the substrate. Moreover, the plurality of piezoelectric actuators is respectively provided for the plurality of structures each having the planar part. Accordingly, it is possible to independently change the distance of the plurality of structures each having the planar part with respect to the one surface of the substrate. That is, it is possible to largely shift the plurality of structures along the direction perpendicular to the in-plane direction at a small pitch.

It is to be noted that the effects of the present disclosure are not necessarily limited to the effects described herein but may be any of the effects described in this specification.

### BRIEF DESCRIPTION OF DRAWINGS

FIG. 1 is a perspective view of a configuration of a display device according to an embodiment of the present disclosure.

FIG. 2 is a perspective view of an example configuration of a display element illustrated in FIG. 1.

FIG. 3 is a perspective view of another example of the configuration of the display element illustrated in FIG. 1.

FIG. 4 is a cross-sectional view of an example of a configuration of an actuator illustrated in FIG. 1.

FIG. 5 is a cross-sectional view of another example of the configuration of the actuator illustrated in FIG. 1.

FIG. 6A is a schematic plan view for explaining the configuration of the actuator illustrated in FIG. 1.

FIG. 6B is a schematic diagram for explaining a modification of the actuator illustrated in FIG. 6A.

FIG. 7 is a plan view of an example of the configuration of the actuator illustrated in FIG. 1.

FIG. 8 is a perspective view for explaining operation of the display element illustrated in FIG. 2.

FIG. 9 is a plan view of another example of the configuration of the actuator illustrated in FIG. 1.

FIG. 10 is a perspective view for explaining operation of the display element illustrated in FIG. 9.

FIG. 11A is a schematic plan view of an example of wire routing of the actuator illustrated in FIG. 1.

FIG. 11B is a schematic cross-sectional view of the wire routing of the actuator illustrated in FIG. 11A.

FIG. 12A is a schematic plan view of another example of the wire routing of the actuator illustrated in FIG. 1.

FIG. 12B is a schematic cross-sectional view of the wire routing of the actuator illustrated in FIG. 12A.

FIG. 13 is a block diagram illustrating a configuration of a display unit according to the present disclosure.

FIG. 14 is a schematic diagram for explaining an optical system in the display unit illustrated in FIG. 13.

FIG. 15 is a perspective view of an example of a configuration of a display element according to a first modification example of the present disclosure.

FIG. 16 is a perspective view of another example of the configuration of the display element according to the first modification example of the present disclosure.

FIG. 17 is a plan view for explaining an array of the display elements illustrated in FIG. 16.

FIG. 18 is a perspective view of a configuration of a display element according to a second modification example of the present disclosure.

FIG. 19 is a perspective view of an appearance of a head-mounted display according to an application example.

### DESCRIPTION OF EMBODIMENTS

In the following, embodiments of the present disclosure are described in detail with reference to the drawings. The following description is a specific example of the present disclosure and the present disclosure should not be limited to the following implementations. Moreover, the present disclosure is not limited to arrangements, dimensions, dimensional ratio, and the like of each component illustrated in the drawings. It is to be noted that the description is made in the following order.

1. Embodiment (an example of a display device allowing a screen surface to shift using piezoelectric actuators)

1-1. Configuration of display device

1-2. Configuration of display unit

1-3. Workings and effects

### 2. Modification Examples

2-1. First modification example (an example using an actuator having different respective widths along two directions orthogonal to each other)

2-2. Second modification example (an example using an actuator having a multi-layer structure)

### 3. Application Example

### 1. Embodiment

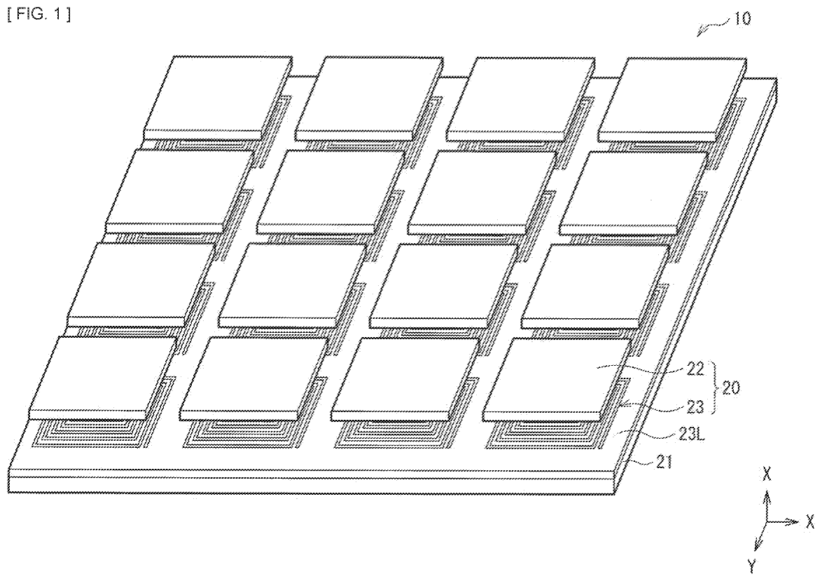

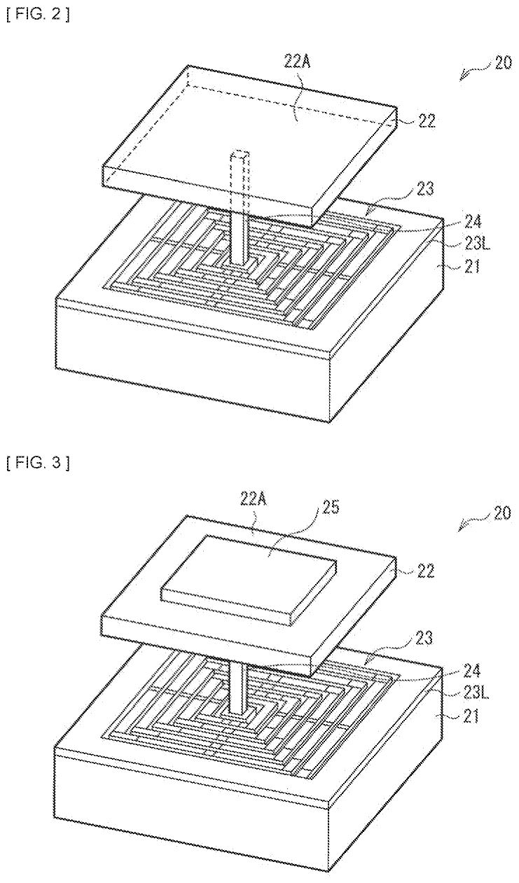

FIG. 1 schematically illustrates a configuration of a semiconductor device (display device 10) according to one embodiment of the present disclosure in perspective view. FIG. 2 schematically illustrates a configuration of a display element 20A illustrated in FIG. 1 in perspective view. The display device 10 is used for a display unit (display unit 1) allowed to display a stereoscopic image described later, for example. The display device 10 according to the embodiment includes a substrate 21, a plurality of structures (structures 22) arranged in a matrix on the substrate 21 and each having a planar part (planar part 22A) that serves as a screen surface, for example, and a plurality of piezoelectric actuators (actuators 23) disposed between the substrate 21 and the plurality of structures 22.

### 1-1. Configuration of Display Device

As described above, the display device 10 includes the plurality of display elements 20A each including the structure 22 and the actuator 23 disposed between the substrate 21 and the structure 22. The display elements 20A are arranged in a matrix on the substrate 21, for example. The structure 22 is coupled to the actuator 23 via a coupling part 24, for example, and the actuator 23 is driven to allow the structure 22 to move in a direction (Z-axis direction) perpendicular to one surface of the substrate 21.

The substrate 21 supports the actuator 23 and the structure 22 coupled to the actuator 23. It is preferable that the substrate 21 should hardly deform, i.e. have high rigidity. For example, the substrate 21 includes a silicon wafer. The substrate 21 is provided with an opening at a position corresponding to the display element 20. The opening opens from a surface opposite from a surface on which the display element 20 is formed (element-formed surface) to the element-formed surface. The opening may have a recessed shape with the substrate 21 remained at the bottom thereof or a through-hole shape penetrating the substrate 21. It is to be noted that the opening may not be provided as long as a sufficient space is ensured between the substrate 21 and the actuator 23 by providing a sacrificial layer between the substrate 21 and the actuator 23, for example.

The structure 22 is a plate-like member having the planar part 22A as described above. For example, the planar part 22A serves as a screen surface, and a front surface of the screen surface preferably has light reflectivity. However, when the planar part 22A serves as, for example, a mirror surface that reflects incident light entering from the Z-axis direction only in a single direction toward the structure 22, a pupil diameter becomes so small that the light could not enter an eye if a user moves his/her eye only slightly. Thus, the planar part 22A is preferably a light diffusing surface that diffuses incident light at a wider angle. For example, the planar part 22A is preferably a rough surface having random irregularity thereon. This makes it possible to achieve a robust optical system in the display unit 1 described later. For example, the structure 22 includes polysilicon provided with a reflective film that includes, for example, aluminum (Al), on its surface. As described above, the plurality of structures 22 is arranged in a matrix on the substrate 21, and each of the structures 22 forms a single pixel.

Moreover, as illustrated in FIG. 3, the planar part 22A of the structure 22 may include one or more light emitting elements 25, such as micro light emitting diodes (LEDs), for example. For example, the planar part 22A of the structure 22 may be mounted with three light emitting elements of red (R), green (G), and blue (B).

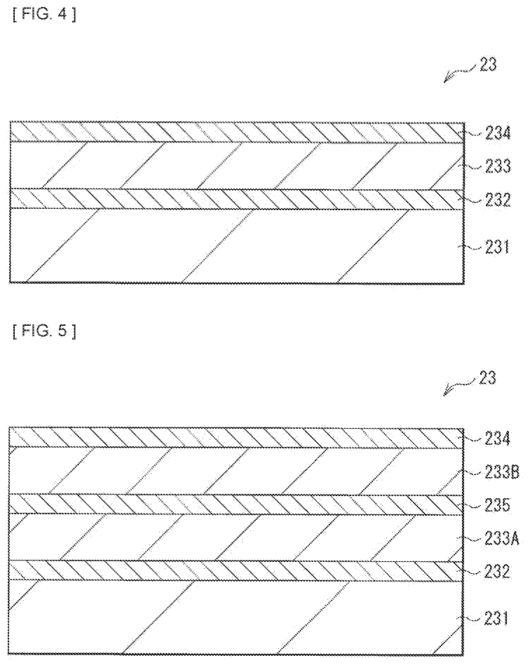

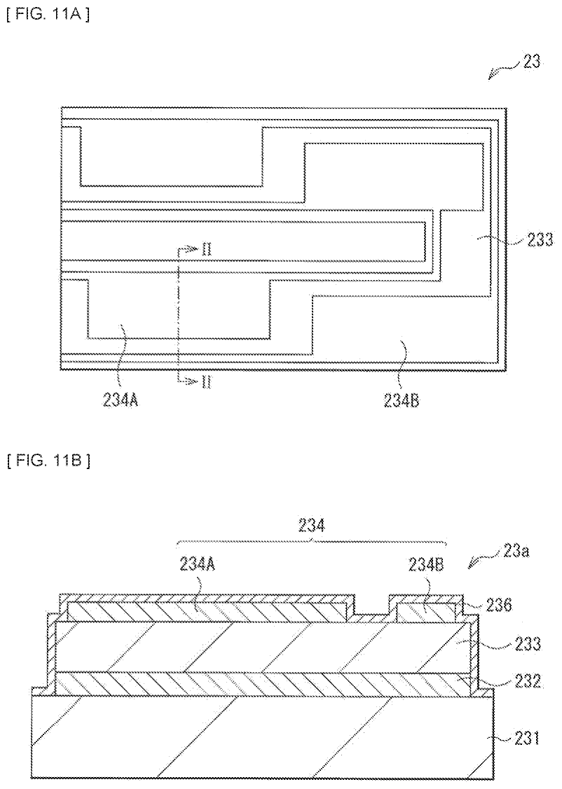

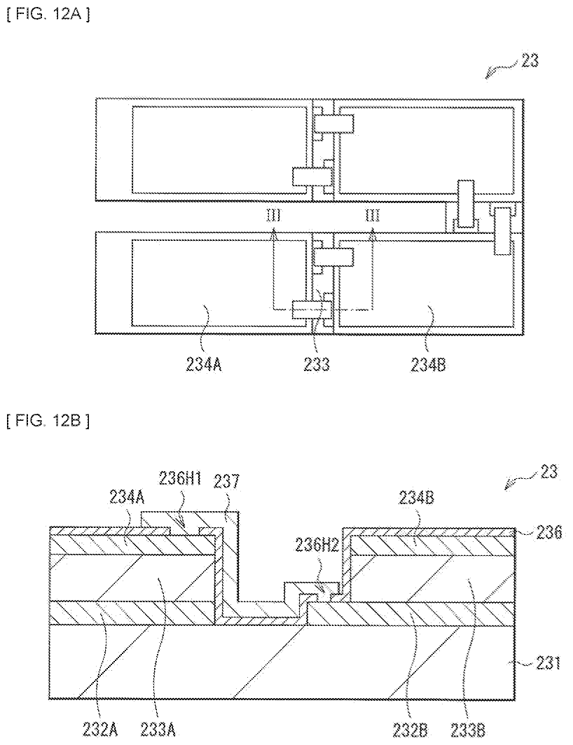

The actuator 23 changes a distance between the planar part 22A of the structure 22 and the substrate 21 by moving the structure 22 along the direction (Z-axis direction) perpendicular to the surface of the substrate 21. Moreover, each of the plurality of actuators 23 disposed on the substrate 21 is provided at a position corresponding to a pixel on an actuator layer 23L disposed on the substrate 21. The actuator 23 is a cantilevered piezoelectric actuator, for example. One end of the actuator 23 is fixed to the substrate 21, and the other end is coupled to the structure 22 via the coupling part 24. The actuator 23 has a so-called unimorph structure including a first electrode film 232, a piezoelectric film 233, and a second electrode film 234 laminated in this order on a support member 231, as illustrated in FIG. 4, for example. Alternatively, the actuator 23 may have a so-called bimorph structure including two piezoelectric films (piezoelectric films 233A and 233B) laminated on the support member 231, as illustrated in FIG. 5, for example. The actuator 23 having the bimorph structure has a structure including the first electrode film 232, the piezoelectric film 233A, a third electrode film 235, the piezoelectric film 233B, and the second electrode film 234 laminated in this order on the support member 231, for example. Mutually inverted voltages are to be applied to the piezoelectric film 233A and the piezoelectric film 233B, which causes high generative force and a larger amount of displacement. It is to be noted that a protective film (protective film 236 (see FIG. 11B, for example)) is disposed on the second electrode film 234 as appropriate.

The actuator 23 according to the embodiment preferably has a configuration including a plurality of units coupled in series. Each of the units is a cantilevered piezoelectric actuator that includes an electrode film (for example, a second electrode film 224) on one surface of a piezoelectric film 223. The electrode film includes a pair of electrodes (electrodes 234A and 234B) to which voltages of reverse polarities are allowed to be applied. This allows the actuator 23 to achieve a relatively large stroke of several tens of μm or more with a small footprint on the order of several tens of μm, for example.

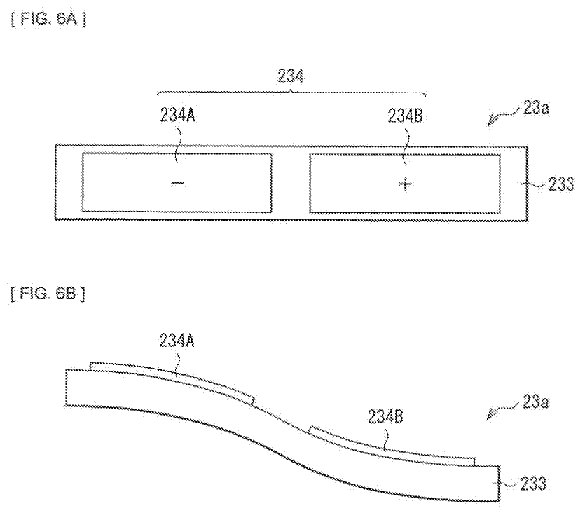

As illustrated in FIG. 6A, for example, each unit 23a that includes the cantilevered piezoelectric actuator has a rectangular shape extending in one axial direction (for example, X-axis direction), and is provided with two electrodes (electrodes 234A and 234B) on one surface (on side of the second electrode film, for example) of the piezoelectric film 233. As described above, voltages of reverse polarities are applied to the two electrodes (electrodes 234A and 234B). That is, the second electrode film 234 illustrated in FIGS. 4 and 5 includes the two electrodes 234A and 234B. When negative potential is applied to one (for example, the electrode 234A) of the electrodes 234A and 234B and positive potential to the other (for example, the electrode 234B), as illustrated in FIG. 6B, the piezoelectric film 233 shrinks on side of the first electrode film 232 in a region corresponding to the electrode 234A, for example, and shrinks on side of the electrode 234B in a region corresponding to the electrode 234B, for example. This causes warpage deformation of the piezoelectric film 233 in the Z-axis direction. That is, the planar part 22A of the structure 22 is coupled to the other end of the actuator 23 one end of which is fixed to the substrate 21, and the planar part 22A of the structure 22 is movable in the direction (Z-axis direction) perpendicular to the surface (X-Y plane) of the substrate 21.

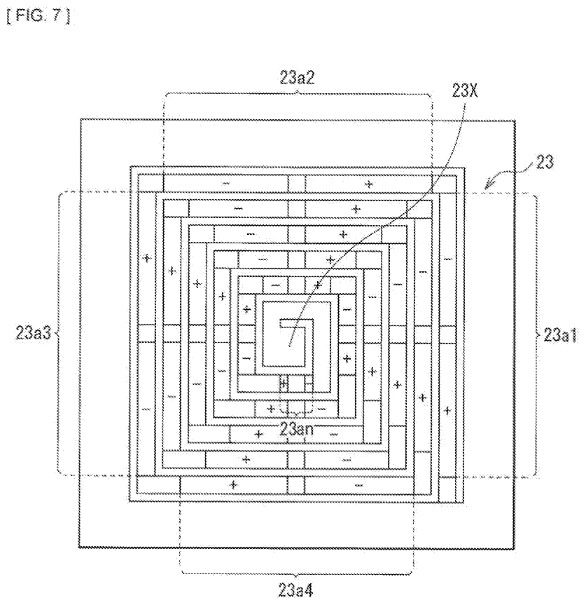

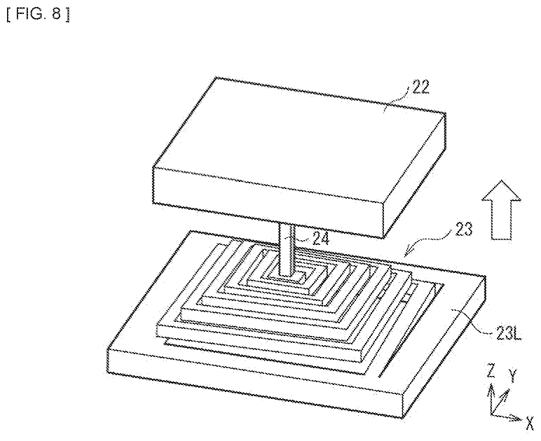

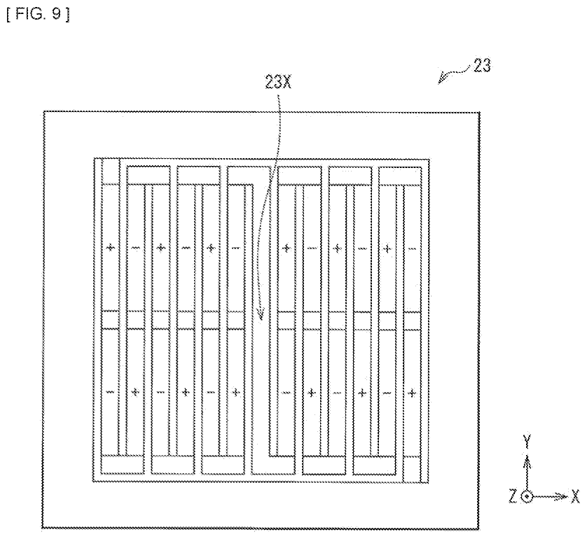

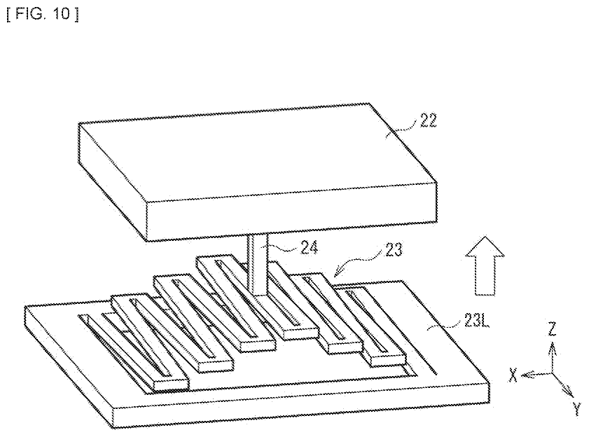

In this embodiment, a plurality of units 23a1 to 23an of the actuator 23 is preferably coupled in series in a spiral shape, as illustrated in FIG. 7, for example. In the actuator 23 having the spiral shape, the plurality of units is coupled to one another such that two electrodes to which voltages of reverse polarities are applied are alternately disposed. Moreover, in the actuator 23 having the spiral shape, one end of one (the unit 23a1 in FIG. 7) of the plurality of units 23a coupled in series is fixed to the substrate 21, and one end of another unit 23a (the unit 23an in FIG. 7) thereof is provided with a holding part 23X for holding the structure 22. The structure 22 is held by the holding part 23X via the coupling part 24. This allows the height of the planar part 22A of the structure 22 with respect to the surface of the substrate 21 to be largely displaced in the Z-axis direction by an amount of the units included in the actuator 23, as illustrated in FIG. 8. It is to be noted that only an outer frame of the actuator 23 is illustrated and illustration of the electrodes 234A and 234B is omitted in FIG. 8. Hereinbelow, the same applies to FIGS. 10, 15, 16, and 18.

Alternatively, the actuator 23 is preferably coupled in series into a meander shape, as illustrated in FIG. 9, for example. For the actuator 23 having the meander shape, it is preferable that the holding part 23X be disposed in the middle of the units 23a juxtaposed in the X-axis direction, for example, and the holding part 23X be coupled to the structure 22 via the coupling part 24. It is also preferable that the plurality of units 23a be disposed such that the two electrodes to which voltages of reverse polarities are applied are alternately disposed starting from the holding part 23X to the end fixed to the substrate 21. This allows the planar part 22A of the structure 22 to be largely displaced in the Z-axis direction, as illustrated in FIG. 10.

As illustrated in FIGS. 11A and 11B, for example, wire routing structures of the electrode 234A and the electrode 234B may be patterned on the piezoelectric film 223. It is to be noted that FIG. 11B illustrates a cross-sectional structure of the actuator 23 taken along a line II-II in FIG. 11A.

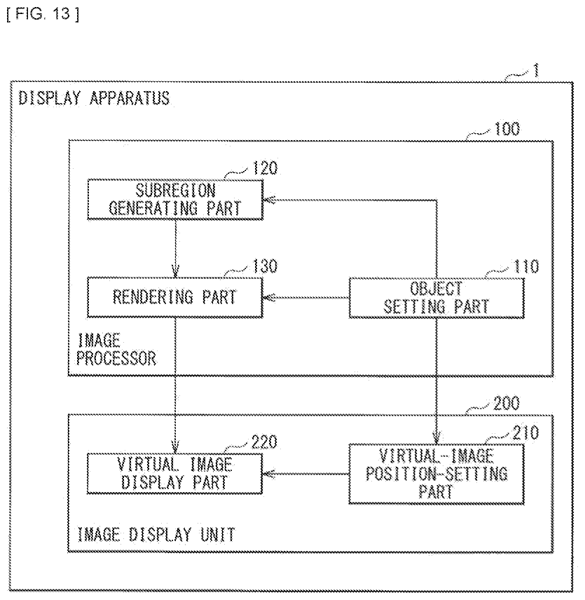

Alternatively, as illustrated in FIGS. 12A and 12B, for example, the electrode 234A and the electrode 234B may have a wire routing structure that includes two laminates in the unit. One of the laminates may include the first electrode film 232 (electrode 232A), the piezoelectric film 233A, and the second electrode film (electrode 234B) that are laminated in this order. The other laminate may include the first electrode film (electrode 232B), the piezoelectric film 233B, and the second electrode film (electrode 234B) laminated in this order. The second electrode (for example, electrode 234A) of the one laminate and the first electrode (for example, electrode 232B) of the other laminate may be electrically coupled via a conductive layer 237. It is to be noted that FIG. 12B illustrates a cross-sectional structure of the actuator 23 taken along a line III-III in FIG. 12A. Moreover, the two laminates and the support member 231 are covered with the protective film 236. The protective film 236 has an opening 236H1 on the electrode 234A and an opening 236H2 on the electrode 232B extending on the adjacent laminate. The conductive layer 237 is electrically coupled to the electrode 234A and the electrode 232B via the openings 236H1 and 236H2, respectively. It is to be noted that the routing structures illustrated in FIGS. 12A and 12B cause higher generative force because areas of the electrode 234A and the electrode 234B are allowed to be maximized.

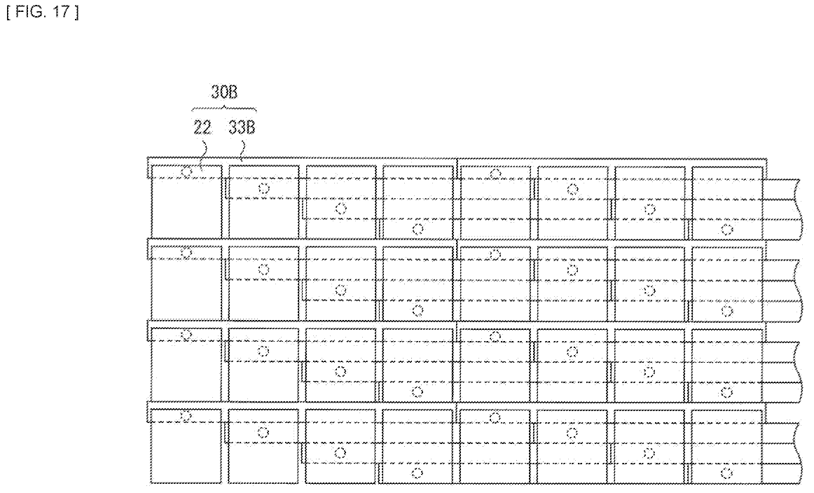

The coupling part 24 couples the structure 22 to the actuator 23. The coupling part 24 preferably has an insulating property, and preferably includes silicon nitride (SiN), for example. The coupling part 24 preferably has a length (l) larger than, for example, a distance of shift of the planar part 22A of the structure 22 with respect to the surface of the substrate 21, i.e., the amount of displacement of the actuator 23 in the Z-axis direction. This is because, as in FIG. 16 illustrating an actuator 33B described later, for example, in a case where the structures 22 of a plurality of display elements 30B each have a sufficiently large width along one of two directions orthogonal to each other and are arranged in a matrix as illustrated in FIG. 17, and where an initial value of the height of the structure 22 is smaller than an amount of displacement of the actuator 33B in the Z-axis direction, the actuator 33B and the structure 22 may interfere with each other in adjacent pixels upon a change in the height of the structure 22 caused by driving the actuator 33B. It is to be noted that the initial value of the structure 22 refers to a distance from the surface of the substrate 21 to the planar part 22A of the structure 22 in a state where the actuator 33B is not driven, for example.

Moreover, the display element 20 according to the embodiment is allowed to reduce the distance between the surface of the substrate 21 and the planar part 22A of the structure 22, i.e., to shift the planar part 22A of the structure 22 toward the substrate 21 in the Z-axis direction, by applying an antiphase voltage to the actuator 23. In this case, it is also possible to prevent interference between the structure 22 and the actuator 23 in adjacent pixels by making the length of the coupling part 24 larger than the amount of displacement of the actuator 33B in the Z-axis direction, as described above.

As described above, in the display device 10 according to the embodiment, the actuator 23 is disposed between the substrate 21 and the structure 22 having the planar part 22A, one end of the actuator 23 is fixed to the substrate 21, and the other end thereof is coupled to the structure 22 via the coupling part 24. This allows the position of the planar part 22A of the structure 22 to largely shift for each pixel in the direction (Z-axis direction) perpendicular to the surface of the substrate 21. Moreover, the display device 10 according to the embodiment makes it possible to achieve a screen array that is movable for each pixel by individually controlling the drive of each of the actuators 23 of each of the display elements 20A.

### 1-2. Configuration of Display Unit

FIG. 13 illustrates a configuration of the display unit 1 according to the present disclosure. The display unit 1 is allowed to display a stereoscopic image. The display unit 1 includes, for example, an image processor 100 and an image display section 200.

The image processor 100 analyzes a binocular disparity included in a stereoscopic video image and obtains depth information of an object appearing in the stereoscopic video image. Specifically, an object setting part 110 obtains a parallax image for a right eye and a parallax image for a left eye that are included in the stereoscopic video image, and the depth information of the object included in the stereoscopic video image.

A subregion generating part 120 divides the stereoscopic video image to be processed into a plurality of subregions on the basis of the depth information obtained by the object setting part 110. A rendering part 130 generates an image that includes pixels respectively included in the plurality of subregions generated by the subregion generating part 120.

The image display section 200 presents the image obtained by the image processor 100 to the user observing the display unit 1. A virtual-image position-setting part 210 sets a position at which a virtual image of the image generated by the rendering part 130 is to be displayed, i.e., a position of the planar part 22A of the structure 22 serving as a screen surface in this embodiment, on the basis of the depth information obtained by the object setting part 110. A virtual image display part 220 presents the virtual image to the user observing the display unit 1 on the basis of the image obtained by the image processor 100.

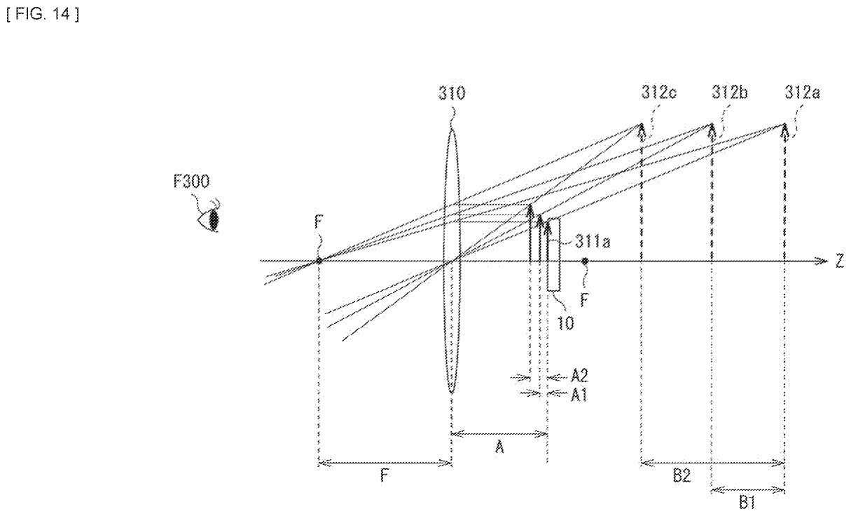

FIG. 14 schematically illustrates a configuration of an optical system included in the above-described display unit 1. The display unit 1 includes, for example, a convex lens 310 and the above-described display device 10 as the optical system. In the display unit 1, a Z axis is defined along a line of sight of a viewpoint 300, and the convex lens 310 and the display device 10 are disposed on the Z axis such that an optical axis of the convex lens 310 and the Z axis match each other. In the display device 10, for example, the screen surface (the planar part 22A of the structure) is disposed at a distance A closer than a focal distance F of a convex lens 27 (A<F) is. That is, the display device 10 is disposed inside a focal point of the convex lens 27. At this time, an image displayed on the display device 10 is observed from the viewpoint 300 as a virtual image at a position away from the convex lens 27 by a distance B (F<B).

The position of the screen surface (planar part 22A) of the display device 10 according to the embodiment shifts in the Z-axis direction. In this display device 10, the planar part 22A is shifted toward the user (viewpoint 300) by a distance A1 or a distance A2 along the Z axis, for example, thereby allowing a position of a virtual image of a real image 311a displayed on the planar part 22A to be shifted from a position 312a toward the user by a distance B1 (virtual image 312b) and by a distance B2 (virtual image 312c), as illustrated in FIG. 14. Especially, the display device 10 according to the embodiment allows the planar part 22A to be shifted for each pixel by several tens of μm, for example. This allows the position of the virtual image observed from the viewpoint 300 to be shifted more largely. That is, it is possible to reproduce distance information of several tens of cm to near infinity for each pixel.

### 1-3. Workings and Effects

As described above, development of a head-mounted 3D display has been in progress in recent years, and a technique using a virtual image obtained by a piston-type array MEMS mirror as a 3D video image is being considered. A MEMS variable-shape mirror that is driven by a static piston array and shifts in the direction perpendicular to an in-plane direction independently in each pixel, and a MEMS deformable mirror that has an integral mirror surface but renders irregularity in the perpendicular direction depending on positional information, are generally used for correcting a wavefront aberration such as adaptive optics. Thus, for such a MEMS-type variable-shape mirror as described above, shape change equal to or smaller than a wavelength of light is sufficient, and an assumed pixel size of the display unit is as large as several hundreds of μm or greater.

For a small display unit such as a head-mounted 3D display, the pixel size is as small as several tens of μm, and the shape change (stroke in the perpendicular direction) of several tens of μm is desired for such a pixel size. However, there has been no MEMES device achieving such a stroke in the perpendicular direction as described above, and it is desired to develop a MEMES device allowed to shift in about several tens of μm in the perpendicular direction at a small pitch (on the order of several tens of μm).

To address this, in the display device 10 according to the embodiment, the plurality of structures 22 each having the planar part 22A is arranged in a matrix, for example, on the substrate 11 via the plurality of actuators 23 that allows each of the plurality of structures 22 to move in the direction perpendicular to the surface of the substrate 21. This makes it possible to independently shift the plurality of structures 22 each having the planar part 22A in the direction (Z-axis direction) perpendicular to the surface of the substrate 21 in a large stroke.

As described above, in this embodiment, the plurality of actuators 23 is disposed between the plurality of structures 22 each having the planar part 22A and the substrate 21, and the plurality of actuators 23 moves each of the plurality of structures 22 along the direction perpendicular to the surface of the substrate 21. This makes it possible to largely change the distance between the planar part 22A of the structure 22 and the surface of the substrate 21. Moreover, the above-described actuator 23 is individually provided for each of the plurality of structures 22 having the planar part 22A. Accordingly, it is possible to independently change the distance of the plurality of structures 22 each having the planar part 22A with respect to the surface of the substrate 21. This allows for a large shift of the planar part 22A along the direction perpendicular to the in-plane direction at a small pitch. That is, in a case where the planar part 22A is formed as a screen surface, it is possible to provide a stereoscopic image display unit that makes it possible to reproduce the depth information of several tens of cm to infinity for each pixel by the virtual image.

Moreover, the actuator 23 according to the embodiment has a configuration including the plurality of units coupled in series, and each of the units is a cantilevered piezoelectric actuator. This allows the actuator 23 to shift in the direction perpendicular to the surface of the substrate 21 as large as several tens of μm or more with a small footprint on the order of several tens of μm, for example. It is thus possible to achieve both the large stroke and the small pixel size, thereby providing the stereoscopic image display unit with higher image quality.

Furthermore, mounting the light emitting element 25, such as a micro LED, on the planar part 22A of the structure 22 makes it possible to achieve the display unit allowed to display a stereoscopic image using a simpler optical system.

### 2. Modification Examples

Next, description is made about modifications examples (first and second modification examples) of the present disclosure. It is to be noted that components corresponding to those of the display device 10 in the above-described embodiment are assigned with the same reference numerals, and description thereof is omitted.

### 2-1. First Modification Example

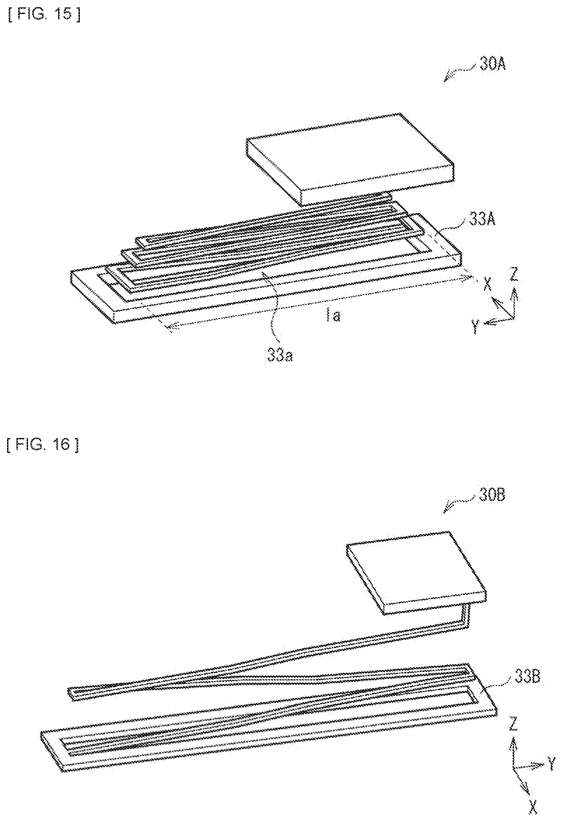

FIGS. 15 and 16 schematically illustrate configurations of display elements (display elements 30A and 30B) according to a modification example (first modification example) of the present disclosure in perspective view. The display element according to the present disclosure allows the amount of displacement of a position of the planar part 22A of the structure 22 with respect to the substrate 21 to increase, as respective widths along two directions orthogonal to each other become more different from each other, i.e. as the shape of the actuator is elongated, as with actuators 33A and 33B of the display elements 30A and 30B of the modification example.

In a case of using the cantilevered piezoelectric actuators as the actuator, in principle, the displacement in the perpendicular direction is approximately proportional to the square of the length. However, as in a case of the display device 10 illustrated in FIG. 1 that includes the actuator for each pixel, it is difficult to make the footprint of the actuator equal to or larger than the size of the structure. Thus, the actuator is formed into an elongated shape to increase the length of each of the units that are the cantilevered piezoelectric actuators included in the actuator, and thereby allowing for a larger displacement.

For example, in a case where the structure 22 has a pitch (length of one side of the structure 22) of 20 μm, and where the actuator 23 has, for example, a square shape having approximately the same size as the structure 22 as in the above-described embodiment, the amount of displacement of each unit 23a including the piezoelectric actuator is about 2 μm. In contrast, as described above, in a case where the actuator (for example, actuator 33A) has a size of 80 μm×5 μm, each unit 33a including the piezoelectric actuator has a length (la) of about 80 μm, and the amount of displacement thereof is about 27 μm, which is equal to or more than twelve times that of the square actuator. Because the area occupied by the actuator is constant, the units each including the piezoelectric actuator and included in the actuator is reduced in number; however, the amount of displacement increases as a result.

Table 1 illustrates a result of calculation of the amount of displacement of the actuator with respect to its longer width (μm). As in the above-described embodiment, the amount of displacement is 2.2 μm with the actuator 23 having a rectangular shape (20 μm×20 μm), whereas the amount of displacement is 11.3 μm with the display element 30A having the size of 40 μm×10 μm (FIG. 15) and 26.9 μm with the display element 30B having the size of 80 μm×5 μm (FIG. 16), for example.

TABLE 1

| | DISPLACEMENT WITH RESPECT TO |
|---|---|
| ACTUATOR SIZE | LONGER WIDTH OF ACTUATOR |
| 20 μm × 20 μm | 2.2 μm |
| 40 μm × 10 μm | 11.3 μm |
| 80 μm × 5 μm | 26.9 μm |

FIG. 17 illustrates an example of a design of the plurality of display elements (for example, display elements 30B) arranged in a matrix, in which each of the plurality of display elements includes a rectangular actuator (for example, actuator 33B), as in the modification example. Even if an aspect ratio of the actuator is changed, the display elements may be arranged in a matrix by shifting each of the actuators 33B by a width of one side of the structure 22, for example, as illustrated in FIG. 17.

### 2-2. Second Modification Example

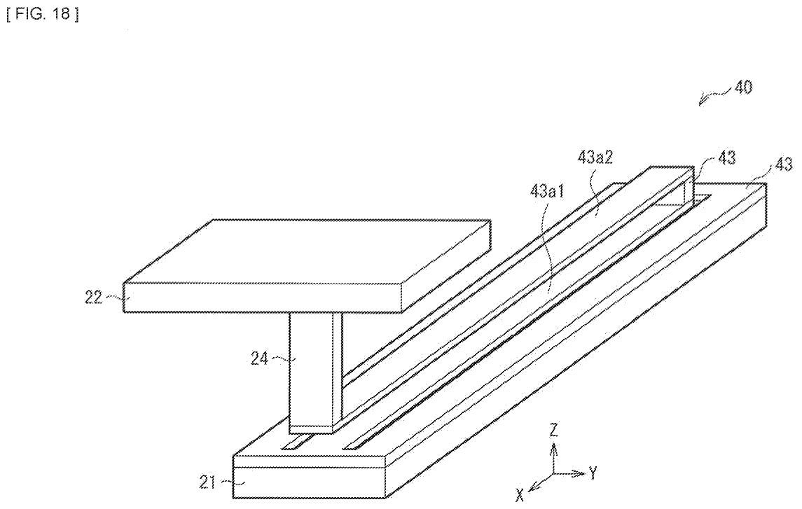

FIG. 18 schematically illustrates a configuration of a display element (display element 40) according to a modification example (second modification example) of the present disclosure in perspective view. The display element 40 according to this modification example is different from the above-described embodiment and the above-described modification example in that the units of the piezoelectric actuator included in an actuator 43 are stacked along the direction (Z-axis direction) perpendicular to the surface of the substrate 21 via a coupling part 46, for example.

Piezoelectric ceramics included in the piezoelectric film 223 includes, for example, lead zirconate titanate (PZT). In general, PZT is difficult to be microfabricated. Moreover, for the necessity of forming a wiring pattern on the piezoelectric film 223, each of the units including the piezoelectric actuator and included in the actuator 43 is actually desired to have a certain beam width (for example, a width in a Y-axis direction in FIG. 18). In this modification example, it is possible to increase the amount of displacement of the position of the planar part 22A of the structure 22 with respect to the substrate 21 while reducing the footprint of the actuator 43 by forming the multi-layer structure (herein, a double-layered structure that includes units 43a1 and 43a2) in which the units each including the piezoelectric actuator and included in the actuator 43 are stacked along the Z-axis direction.

### 3. Application Example

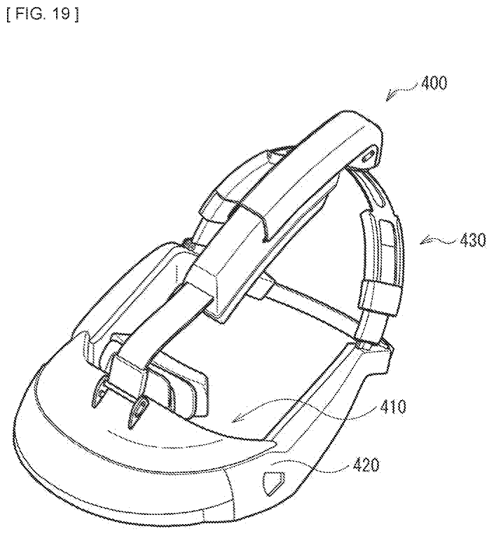

As illustrated in FIG. 19, the display unit 1 including the display device 10 according to the present disclosure is applicable to a wearable display, such as a head-mounted display as described above, a portable display that may be carried, or an electronic apparatus, such as a smartphone and a tablet, as described above. A schematic configuration of a head-mounted display 400 is described as one example.

The head-mounted display 400 includes, for example, a display part 410, a housing 420, and an attachment 430. The display part 410 displays a stereoscopic video image having depth. Specifically, the display part 410 separately displays a parallax image for a right eye and a parallax image for a left eye. This allows a stereoscopic video image having depth to be displayed on the display part 410.

The housing 420 serves as a frame of the display unit 1. The housing 420 accommodates various modules, such as various optical components (not illustrated), included in the display unit 1.

It is to be noted that, although a hat-type head-mounted display to be put on a head of a user is described as an example in this modification example, this modification example is applicable to a display unit having any other shape, such as a glasses-type head-mounted display, for example, in addition to the example.

Moreover, the semiconductor device according to the present disclosure may be used as a haptic device as well as the display device, by rapidly oscillating each actuator, for example.

Although the present disclosure has been described with reference to the embodiment and the modification examples (first and second modification examples) hereinabove, the present disclosure is not limited to the above-described embodiment and the like, and various modifications may be made.

It is to be noted that the effects described herein are merely examples. The effects of the present disclosure are not limited to those described in this specification. The present disclosure may have effects other than those described in this specification.

Moreover, for example, the present disclosure may have the following configurations.

(1) A semiconductor device, including:

a substrate;

a plurality of structures arranged in a matrix and each having a planar part; and

a plurality of piezoelectric actuators disposed on the substrate and configured to move each of the plurality of structures along a direction perpendicular to one surface of the substrate.

(2) The semiconductor device according to (1), in which the planar part of each of the plurality of structures has a light reflecting surface.
(3) The semiconductor device according to (1) or (2), in which the planar part of each of the plurality of structures includes one or more light emitting elements mounted thereon.
(4) The semiconductor device according to any one of (1) to (3), in which the piezoelectric actuator includes a cantilevered actuator.
(5) The semiconductor device according to (4), in which the piezoelectric actuator includes a plurality of the cantilevered actuators coupled in series.
(6) The semiconductor device according to any one of (1) to (5), in which each of the plurality of piezoelectric actuators has widths along two directions orthogonal to each other, the widths being different from each other.
(7) The semiconductor device according to any one of (1) to (6), in which each of the plurality of piezoelectric actuators has a spiral shape.
(8) The semiconductor device according to any one of (1) to (7), in which each of the plurality of piezoelectric actuators has a meander shape.
(9) The semiconductor device according to any one of (1) to (8), in which each of the plurality of piezoelectric actuators has a multi-layer structure.
(10) The semiconductor device according to any one of (1) to (9), in which each of the plurality of piezoelectric actuators has a unimorph structure.
(11) The semiconductor device according to any one of (1) to (10), in which each of the plurality of piezoelectric actuators has a bimorph structure.
(12) The semiconductor device according to any one of (1) to (11), in which the plurality of structures and the plurality of piezoelectric actuators are coupled to each other by respective coupling parts.
(13) The semiconductor device according to (12), in which the coupling parts each have a length longer than a distance of shift of each of the structures with respect to the one surface of the substrate, the shift being caused by each of the piezoelectric actuators.
(14) A display unit including:

an optical system including a lens and a display device,

in which the display device includes

a substrate,

a plurality of structures arranged in a matrix and each having a planar part, and

a plurality of piezoelectric actuators disposed on the substrate and configured to move each of the plurality of structures along a direction perpendicular to one surface of the substrate.

(15) An electronic apparatus including:

a display unit including an optical system, the optical system including a lens and a display device,

in which the display device includes

a substrate,

a plurality of structures arranged in a matrix, and

a plurality of piezoelectric actuators disposed on the substrate and configured to move each of the plurality of structures along a direction perpendicular to one surface of the substrate.

This application claims the priority of Japanese Patent Application No. 2016-205224 filed with the Japanese Patent Office on Oct. 19, 2016, the entire contents of which are incorporated herein by reference.

Those skilled in the art could assume various modifications, combinations, sub-combinations, and changes in accordance with design requirements and other factors. However, it is understood that they are included within the scope of the appended claims or the equivalents thereof.

1. A semiconductor device, comprising:
a substrate;
a plurality of structures arranged in a matrix and each having a planar part; and
a plurality of piezoelectric actuators disposed on the substrate and configured to move each of the plurality of structures along a direction perpendicular to one surface of the substrate.

2. The semiconductor device according to claim 1, wherein the planar part of each of the plurality of structures has a light reflecting surface.

3. The semiconductor device according to claim 1, wherein the planar part of each of the plurality of structures includes one or more light emitting elements mounted thereon.

4. The semiconductor device according to claim 1, wherein the piezoelectric actuator comprises a cantilevered actuator.

5. The semiconductor device according to claim 4, wherein the piezoelectric actuator includes a plurality of the cantilevered actuators coupled in series.

6. The semiconductor device according to claim 1, wherein each of the plurality of piezoelectric actuators has widths along two directions orthogonal to each other, the widths being different from each other.

7. The semiconductor device according to claim 1, wherein each of the plurality of piezoelectric actuators has a spiral shape.

8. The semiconductor device according to claim 1, wherein each of the plurality of piezoelectric actuators has a meander shape.

9. The semiconductor device according to claim 1, wherein each of the plurality of piezoelectric actuators has a multi-layer structure.

10. The semiconductor device according to claim 1, wherein each of the plurality of piezoelectric actuators has a unimorph structure.

11. The semiconductor device according to claim 1, wherein each of the plurality of piezoelectric actuators has a bimorph structure.

12. The semiconductor device according to claim 1, wherein the plurality of structures and the plurality of piezoelectric actuators are coupled to each other by respective coupling parts.

13. The semiconductor device according to claim 12, wherein the coupling parts each have a length longer than a distance of shift of each of the structures with respect to the one surface of the substrate, the shift being caused by each of the piezoelectric actuators.

14. A display unit comprising:
an optical system including a lens and a display device,
wherein the display device includes
a substrate,
a plurality of structures arranged in a matrix and each having a planar part, and
a plurality of piezoelectric actuators disposed on the substrate and configured to move each of the plurality of structures along a direction perpendicular to one surface of the substrate.

15. An electronic apparatus comprising:
a display unit including an optical system, the optical system including a lens and a display device,
wherein the display device includes
a substrate,
a plurality of structures arranged in a matrix, and
a plurality of piezoelectric actuators disposed on the substrate and configured to move each of the plurality of structures along a direction perpendicular to one surface of the substrate.
